(19) United States
(12) Patent Application Publication
(10) Pub. No.: US 2014/0354261 A1
(43) Pub. Date: Dec. 4, 2014

(54) METHOD, CIRCUIT AND INTEGRATED CIRCUIT FOR DETECTING RESONANCE FREQUENCY

(71) Applicant: Fairchild Semiconductor Corporation, San Jose, CA (US)

(72) Inventors: Lei Huang, Beijing (CN); Na Meng, Beijing (CN)

(21) Appl. No.: 14/291,609

(22) Filed: May 30, 2014

(30) Foreign Application Priority Data
May 30, 2013 (CN) 201310217647.5

(51) Int. Cl. G01R 23/10

(52) U.S. Cl. CPC G01R 23/10
USPC 324/76.39

(57) ABSTRACT

A method, circuit, and integrated circuit for detecting resonance frequency is disclosed in which a first operational amplifier circuit receives an input signal and provides an output signal for a resonance circuit to store energy, a zero crossing comparator circuit samples a discharge current of the resonance circuit and transforms the sampled current into a sampled voltage and outputs a square signal to a digital signal processor based on the sampled voltage, and the digital signal processor obtains a resonance frequency based on the square signal.

### CLAIM OF PRIORITY

The application claims the benefit of priority under 35 U.S.C. §119(a) to Lei Huang et al., CN Application No. 201310217647.5, filed on May 30, 2013, which is hereby incorporated by reference in its entirety.

### TECHNICAL FIELD

The disclosure relates to a frequency detection technology for an integrated circuit, and more specifically, to a method, a circuit and an integrated circuit for detecting resonance frequency.

### BACKGROUND

An appropriate driving frequency is required for a resonance circuit in an integrated circuit to generate a resonance. However, even for integrated circuits which are manufactured by employing a same process, their resonance circuits may have different resonance frequencies, i.e., the resonance frequencies may vary from each other. Accordingly, there is a need for a simple and accurate method to detect a resonance frequency of a resonance circuit in an integrated circuit.

### OVERVIEW

In view of the above, a method, a circuit and an integrated circuit for detecting resonance frequency are provided as follows.

In an embodiment, a resonance frequency detection circuit is provided. The circuit includes a first operational amplifier circuit, a resonance circuit, a zero crossing comparator circuit, and a digital signal processor. The first operational amplifier circuit can be configured to receive an input signal and to provide an output signal for the resonance circuit to store energy. The resonance circuit can be configured to store energy based on the output signal of the first operational amplifier circuit, and to discharge after the input signal is disabled. The zero crossing comparator circuit can be configured to sample a discharge current of the resonance circuit after the input signal is disabled, to transform the sampled discharge current to a sampled voltage, and to output a square signal to the digital signal processor based on variation of the sampled voltage. The digital signal processor can be configured to obtain a resonance frequency based on the square signal.

In an embodiment, a method for detecting resonance frequency comprises the following steps: at an operational amplifier circuit, receiving an input signal; providing an output signal for a resonance circuit to store energy; sampling a discharge current of the resonance circuit after the input signal is disabled; transforming the sampled discharge current into a sampled voltage; outputting a square signal based on the sampled voltage; and obtaining a resonance frequency based on the square signal.

In an embodiment, an integrated circuit comprises a resonance frequency detection circuit. The resonance frequency detection circuit includes a first operational amplifier circuit, a resonance circuit, a zero crossing comparator circuit, and a digital signal processor. The first operational amplifier circuit can be configured to receive an input signal and to provide an output signal for the resonance circuit to store energy. The resonance circuit can be configured to store energy based on the output signal of the first operational amplifier circuit, and to discharge after the input signal is disabled. The zero crossing comparator circuit can be configured to sample a discharge current of the resonance circuit after the input signal is disabled, to transform the sampled discharge current to a sampled voltage, and to output a square signal to the digital signal processor based on variation of the sampled voltage. The digital signal processor can be configured to obtain the resonance frequency based on the square signal.

According to various embodiments of the disclosure, the first operational amplifier circuit receives an input signal and provides an output signal for the resonance circuit to store energy; the zero crossing comparator circuit samples a discharge current of the resonance circuit and transforms the sampled current into a sampled voltage and outputs a square signal to the digital signal processor based on the sampled voltage; the digital signal processor obtains a resonance frequency based on the square signal. As such, when the discharge current of the resonance circuit is being sampled, the first operational amplifier circuit is in a zero output state, which ensures the detection accuracy, reduces the complexity of the detection circuit and saves the space and cost of the integrated circuit.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a schematic diagram of the structure of an existing resonance frequency detection circuit.

FIG. 2 is a schematic diagram of the structure of a resonance frequency detection circuit according to an embodiment of the disclosure.

FIG. 3 is a schematic diagram illustrating the principle of a resonance frequency detection circuit according to a first embodiment of the disclosure.

FIG. 4 is a schematic diagram illustrating the principle of the resonance frequency detection circuit in an energy storage state according to the first embodiment of the disclosure.

FIG. 5 is a schematic diagram illustrating the principle of the resonance frequency detection circuit in a detection state according to the first embodiment of the disclosure.

FIG. 6 is a schematic diagram illustrating the principle of a resonance frequency detection circuit according to a second embodiment of the disclosure.

FIG. 7 is a schematic diagram illustrating the principle of the structure of a positive output of an operational amplifier in the second embodiment of the disclosure.

FIG. 8 shows a discharge waveform of a resonance circuit and an input simulation waveform of an A/D converter or a comparator in the second embodiment of the disclosure.

FIG. 9 is a flow chart of a method for detecting resonance frequency according to an embodiment of the disclosure.

FIG. 10 is a schematic diagram of an equivalent circuit of the LC oscillating circuit according to an embodiment of the disclosure.

### DETAILED DESCRIPTION

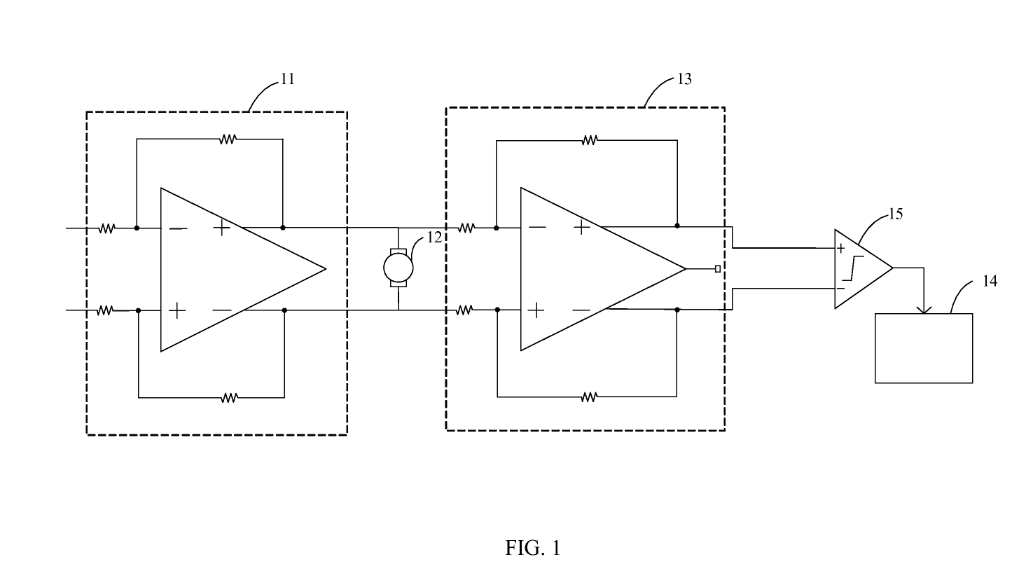

An existing resonance frequency detection circuit is shown in FIG. 1. A first operational amplifier circuit 11 receives an input signal and provides an output signal for a resonance circuit 12 to store energy. The second operational amplifier circuit 13 amplifies a discharge voltage of the resonance circuit 12 after the output signal of the first operational amplifier circuit 11 is disabled and sends the amplified discharge voltage to a comparator circuit 15. The comparator circuit 15 outputs a square signal to a digital signal processor 14 based on the amplified discharge voltage. The digital signal processor 14 obtains a resonance frequency based on the square signal.

According to various aspects of the disclosure, a first operational amplifier circuit receives an input signal and provides an output signal for a resonance circuit to store energy; a zero crossing comparator circuit samples, after the input signal is disabled, a discharge current of the resonance circuit and transforms the sampled current into a sampled voltage and outputs a square signal to a digital signal processor based on the sampled voltage; and the digital signal processor obtains a resonance frequency based on the square signal.

The subject matter will be described in detail with reference to the accompanying drawings and particular embodiments.

In an embodiment, a resonance frequency detection circuit is provided. As shown in FIG. 2, the circuit includes a first operational amplifier circuit 11, a resonance circuit 12, a zero crossing comparator circuit 16 and a digital signal processor 14.

The first operational amplifier circuit 11 can be configured to receive an input signal and to provide an output signal for the resonance circuit 12 to store energy. The resonance signal 12 can be configured to store energy based on the output signal of the first operational amplifier circuit 11, and to discharge after the input signal is disabled.

The zero crossing comparator circuit 16 can be configured to sample a discharge current of the resonance circuit 12 after the input signal is disabled, to transform the sampled discharge current to a sampled voltage, and to output a square signal to the digital signal processor 14 based on variation of the sampled voltage. The digital signal processor 14 can be configured to obtain a resonance frequency based on the square signal.

Specifically, the digital signal processor 14 may be configured to determine a portion of the square signal corresponding to a first (beginning) cycle and to calculate a cycle period of the portion based on a clock frequency. Alternatively, the digital signal processor 14 may be configured to determine a first portion of the square signal corresponding to the first cycle and a second portion of the square signal corresponding to a second cycle following the first cycle, to calculate the cycle period of each of the first and second portions based on the clock frequency, to take an average of the cycle periods of the first and second portions, or perform an offset trimming on the cycle periods of the first and second portions, and then take either of them.

The clock frequency may be provided by a built-in oscillator, or may be provided by an external clock. The portion of the square signal corresponding to the first cycle may be determined by detecting first two adjacent rising edges or falling edges of the square signal, and determining a portion between the first two adjacent rising edges or the first two falling edges as the portion of the square signal corresponding to the first cycle.

The first and second portions of the square signal corresponding to the first and second cycles may be determined by detecting first two adjacent rising edges or falling edges of the square signal, determining a portion between the first two adjacent rising edges or the first two falling edges as the first portion of the square signal corresponding to the first cycle, and then selecting another portion that lags behind the first portion a half cycle as second portion of the square signal corresponding to the second cycle.

The resonance circuit can include an LC oscillator, a linear resonant actuator (LRA), or the like. In an equivalent circuit of the LC oscillator as shown in FIG. 10, an impedance element Z and a resonance inductor Ls form a serial loop, and each of a resonance capacitor Cs and a resonance resistor Rs is connected to the resonance inductor Ls in parallel.

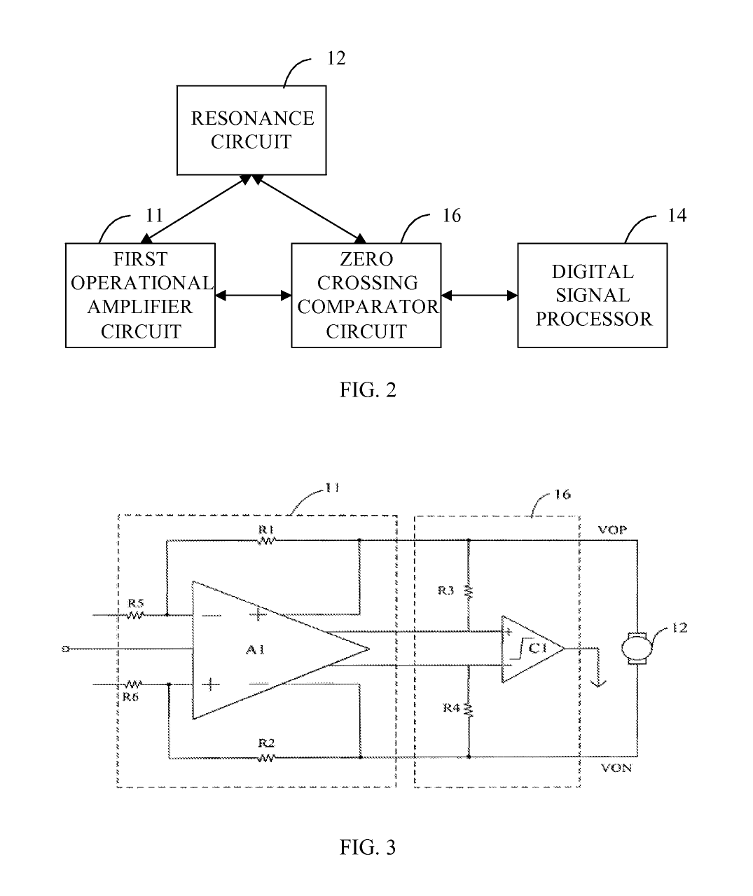

FIG. 3 is a schematic diagram illustrating the principle of a first resonance frequency detection circuit according to the disclosure. The circuit includes a first operational amplifier circuit 11, a resonance circuit 12, a zero crossing comparator circuit 16, and a digital signal processor. The first operational amplifier circuit 11 includes an operational amplifier A1, a first feedback resistor R1, a second feedback resistor R2, a first input resistor R5, and a second input resistor R6. The zero crossing comparator circuit 16 includes an A/D converter or a comparator C1, a first sampling resistor R3, and a second sampling resistor R4.

The first feedback resistor R1 is connected between a negative input of the operational amplifier A1 and a positive output of the operational amplifier A1, and the first input resistor R5 is also connected to the negative input of the operational amplifier A1. The second feedback resistor R2 is connected between a positive input of the operational amplifier A1 and a negative output of the operational amplifier A1, and the second input resistor R6 is also connected to the positive input of the operational amplifier A1. The positive output of the operational amplifier A1 is connected with a positive input of the A/D converter or the comparator C1 as well as a positive output of the resonance circuit 12, and the negative output of the operational amplifier A1 is connected with a negative input of the A/D converter or the comparator C1 as well as a negative output of the resonance circuit 12.

The first sampling resistor R3 is connected between the positive input of the A/D converter or the comparator C1 and the positive output of the resonance circuit 12, and the second sampling resistor R4 is connected between the negative input of the A/D converter or the comparator C1 and the negative output of the resonance circuit 12. An output of the A/D converter or the comparator C1 is connected with the digital signal processor (not shown in FIG. 3).

In the detection circuit as shown in FIG. 3, each of the positive and the negative inputs of the A/D converter or the comparator C1 may also be connected with a respective grounded filter capacitor.

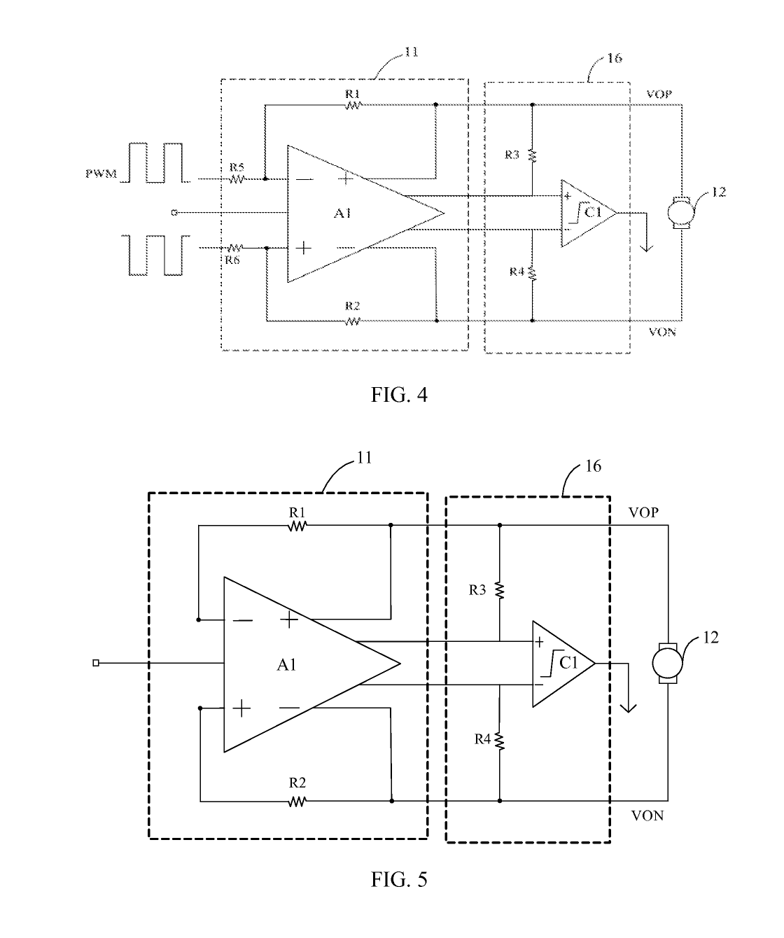

FIG. 4 is a schematic diagram illustrating the principle of the first resonance frequency detection circuit in an energy storage state according to the disclosure, and FIG. 5 is a schematic diagram illustrating the principle of the first resonance frequency detection circuit in a detection state according to the disclosure.

FIG. 4 illustrates the energy storage state of the first resonance frequency detection circuit. The operational amplifier A1 receives an input signal via the first input resistor R5 and the second input resistor R6, and provides, based on the input signal, an output signal to the output of the resonance circuit 12, causing the resonance circuit 12 to store energy. The input signal may be a pulse width modulation (PWM) signal that depends on a duty cycle, or an analog signal.

FIG. 5 illustrates the detection state of the first resonance frequency detection circuit. In the detection state, the input signal is disabled, and the operational amplifier A1, the first feedback resistor R1, and the second feedback resistor R2 form a follower. Since the input of the operational amplifier A1 is zero, the output of the operational amplifier A1 is also zero, the resonance circuit 12 starts to discharge between its positive and negative outputs, and the positive and negative outputs of the resonance circuit 12 are connected to the positive and the negative inputs of the A/D converter or the comparator C1 via the first sampling resistor R3 and the second sampling circuit R4, respectively. The A/D converter or the comparator C1 compares the voltages at the positive and negative inputs, when the voltage at the positive input of the A/D converter or the comparator C1 is greater than the voltage at the negative input of the A/D converter or the comparator C1, the A/D converter or the comparator C1 will output a high level signal, and when the voltage at the positive input of the A/D converter or the comparator C1 is smaller than the voltage at the negative input of the A/D converter or the comparator C1, the A/D converter or the comparator C1 will output a low level.

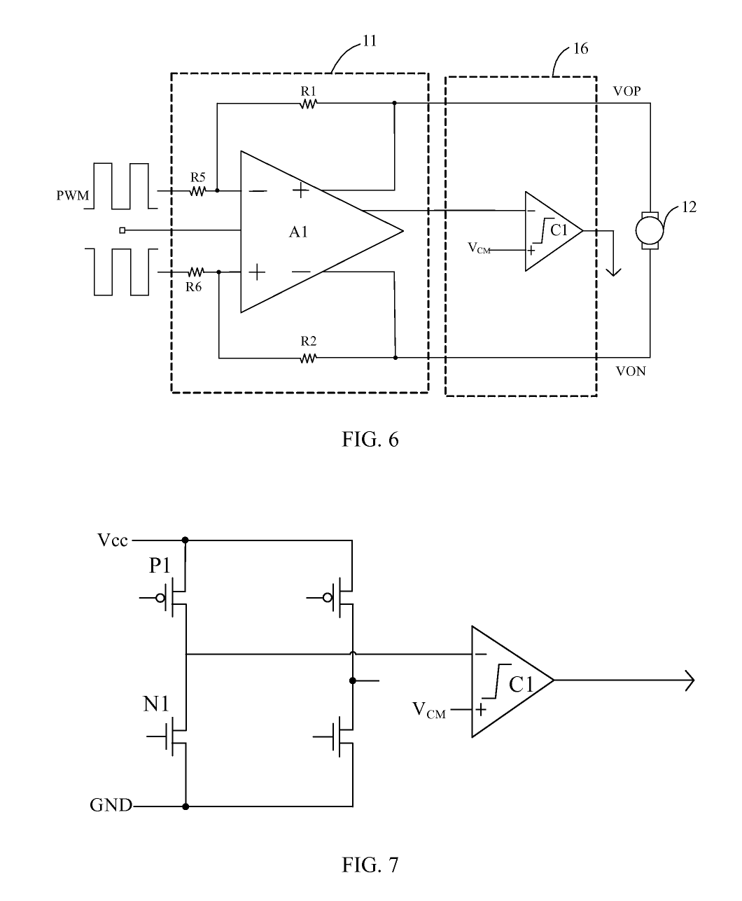

FIG. 6 is a schematic diagram illustrating the principle of a second resonance frequency detection circuit according to the disclosure. The circuit includes a first operational amplifier circuit 11, a resonance circuit 12, a zero crossing comparator circuit 16, and a digital signal processor. The first operational amplifier circuit 11 includes an operational amplifier A1, a first feedback resistor R1, a second feedback resistor R2, a first input resistor R5, and a second input resistor R6. The zero crossing comparator circuit 16 includes an A/D converter or a comparator C1.

The first feedback resistor R1 is connected between a negative input of the operational amplifier A1 and a positive output of the operational amplifier A1, and the first input resistor R5 is also connected to the negative input of the operational amplifier A1. The second feedback resistor R2 is connected between a positive input of the operational amplifier A1 and a negative output of the operational amplifier A1, and the second input resistor R6 is also connected to the positive input of the operational amplifier A1. The positive output of the operational amplifier A1 is connected with a negative input of the A/D converter or the comparator C1 as well as a positive output of the resonance circuit 12, and the negative output of the operational amplifier A1 is connected with a negative output of the resonance circuit 12.

The positive input of the A/D converter or the comparator C1 is connected with a reference voltage VCM, and the output of the A/D converter or the comparator C1 is connected with the digital signal processor (not shown in FIG. 6).

In the detection circuit as shown in FIG. 6, the negative input of the A/D converter or the comparator C1 may also be connected with a grounded filter capacitor.

When the detection circuit as shown in FIG. 6 is in an energy storage state, the operational amplifier A1 receives an input signal via the first input resistor R5 and the second input resistor R6, and provides, based on the input signal, an output signal to the output of the resonance circuit 12, causing the resonance circuit 12 to store energy.

When the detection circuit as shown in FIG. 6 is in a detection state, the input signal is disabled, and the operational amplifier A1, the first feedback resistor R1 and the second feedback resistor R2 form a follower. Since the input of the operational amplifier A1 is zero, the output of the operational amplifier A1 is also zero, and the resonance circuit 12 starts to discharge between its positive and negative outputs, and generates an induced voltage to the A/D converter or the comparator C1 through an internal resistor at the positive output of the operational amplifier A1. The A/D converter or the comparator C1 compares the voltages at the positive and negative inputs, when the voltage at the positive input of the A/D converter or the comparator C1 is greater than the voltage at the negative input of the A/D converter or the comparator C1, the A/D converter or the comparator C1 will output a high level signal, and when the voltage at the positive input of the A/D converter or the comparator C1 is smaller than the voltage at the negative input of the A/D converter or the comparator C1, the A/D converter or the comparator C1 will output a low level.

The structure of the positive output of the operational amplifier A1 is shown in FIG. 7. The positive output of the operational amplifier A1 is formed by a first PMOS P1 and a first NMOS N1 connected in series. The first P-channel Metal Oxide Semiconductor transistor (PMOS) P1 and the first N-channel Metal Oxide Semiconductor transistor (NMOS) N1 are in serial connection with each other between a supply voltage Vcc and a ground GND. A drain of the first PMOS P1 is connected with a drain of the first NMOS N1, and is connected with the negative input of the A/D converter or the comparator C1.

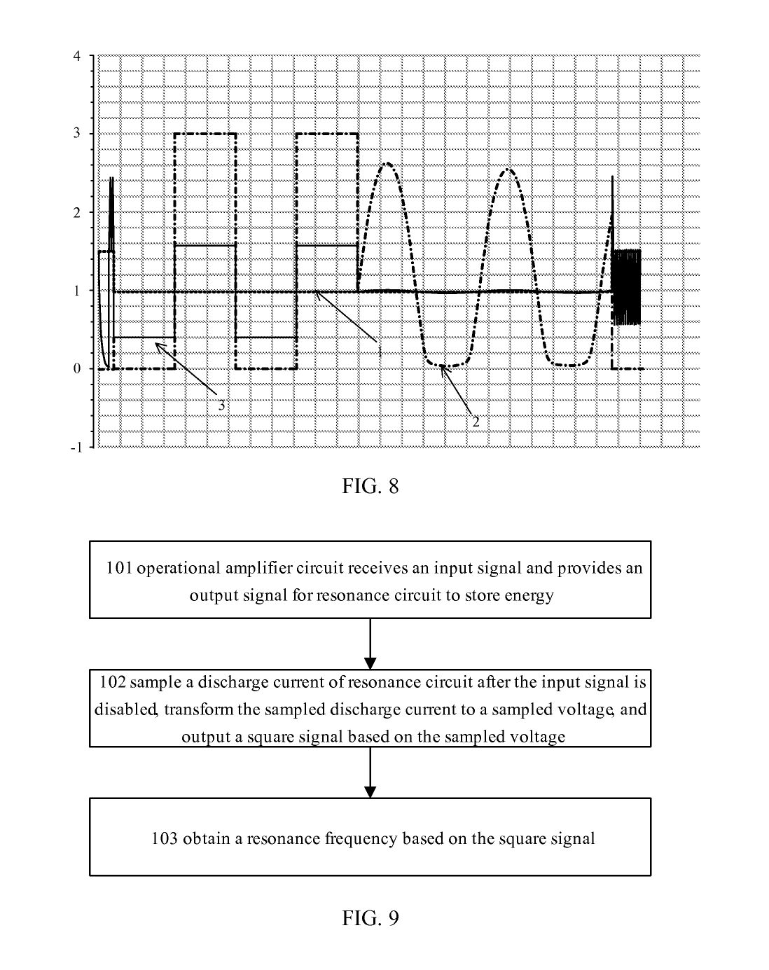

FIG. 8 shows a discharge waveform of the resonance circuit and an input simulation waveform of the A/D converter or the comparator when the detection circuit as shown in FIG. 6 is in the detection state. The flat dashed line 1 represents the reference voltage VCM at the positive input of the A/D converter or the comparator C1, the wavy dashed line 2 represents the induced voltage at the negative input of the A/D converter or the comparator C1, and the wavy solid line 3 represents the discharge waveform of the resonance circuit 12. As can be seen from FIG. 8, when the resonance circuit 12 discharges up to the resonance frequency, the induced voltage at the negative input of the A/D converter or the comparator C1 will present a curve similar to a sine (or cosine) waveform.

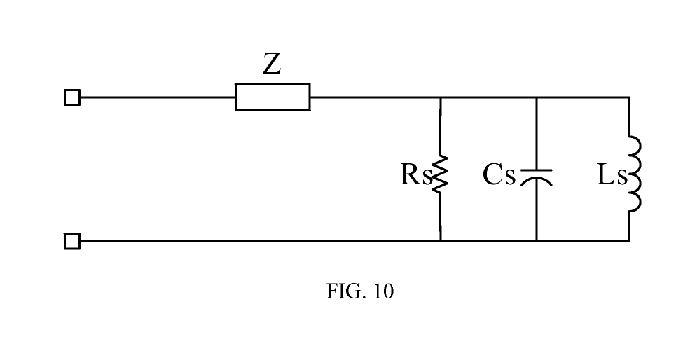

Based on the aforementioned resonance frequency detection circuit, the disclosure further provides a method of detecting resonance frequency. As shown in FIG. 9, the method includes the following steps.

At step 101, an operational amplifier circuit receives an input signal, and provides an output signal for a resonance circuit to store energy.

At step 102, after the input signal is disabled, a discharge current of the resonance circuit is sampled and transformed to a sampled voltage, and a square signal is output based on the sampled voltage.

In particular, the discharge currents at both outputs of the resonance circuit are sampled and transformed into sampled voltages, the two sampled voltages are compared to output a square signal.

Alternatively, the discharge current at one output of the resonance circuit is sampled and transformed into a sampled voltage, the sampled voltage is compared with a predetermined reference voltage to output a square signal.

At step 103, a resonance frequency is obtained based on the square signal.

In particular, a portion of the square signal corresponding to a first (beginning) cycle may be determined and a cycle period of the square signal may be calculated based on a clock frequency. Alternatively, a first portion of the square signal corresponding to the first cycle and a second portion of the square signal corresponding to a second cycle following the first cycle may be determined, the cycle period of each of the first and second portions may be calculated based on the clock frequency, and the cycle periods of the first and second portions may be averaged, or an offset trimming may be performed on the cycle periods of the first and second portions, and then either of them may be taken as the cycle period of the square signal.

The clock frequency may be provided by a built-in oscillator, or may be provided by an external clock. The portion of the square signal corresponding to the first cycle may be determined by detecting first two adjacent rising edges or falling edges of the square signal and determining a portion between the first two adjacent rising edges or the first two falling edges as the portion of the square signal corresponding to the first cycle.

The first and second portions of the square signal corresponding to the first and second cycles may be determined by detecting first two adjacent rising edges or falling edges of the square signal, determining a portion between the first two adjacent rising edges or the first two falling edges as the first portion of the square signal corresponding to the first cycle, and then selecting another portion that lags behind the first portion a half cycle as second portion of the square signal corresponding to the second cycle.

Based on the above-mentioned resonance frequency detection circuit, the disclosure further provides an integrated circuit including the resonance frequency detection circuit, such as described above.

The above description is only the preferred embodiments of the disclosure, and is not intended to limit the scope thereof

### ADDITIONAL NOTES AND EXAMPLES

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A resonance frequency detection circuit, comprising:
a first operational amplifier circuit;
a resonance circuit;
a zero crossing comparator circuit; and
a digital signal processor,
wherein the first operational amplifier circuit is configured to receive an input signal and to provide an output signal for the resonance circuit to store energy,
wherein the resonance circuit is configured to store energy based on the output signal of the first operational amplifier circuit, and to discharge after the input signal is disabled,
wherein the zero crossing comparator circuit is configured to sample a discharge current of the resonance circuit after the input signal is disabled, to transform the sampled discharge current to a sampled voltage, and to output a square signal to the digital signal processor based on variation of the sampled voltage, and
wherein the digital signal processor is configured to obtain a resonance frequency based on the square signal.

2. The circuit according to claim 1, wherein the digital signal processor is configured to:
determine a portion of the square signal corresponding to a first cycle; and
calculate, based on a clock frequency, a cycle period of the portion as the cycle period of the square signal; or wherein the digital signal processor is configured to:
determine a first portion of the square signal corresponding to the first cycle and a second portion of the square signal corresponding to a second cycle following the first cycle;
calculate the cycle period of each of the first and second portions based on the clock frequency; and
take an average of the cycle periods of the first and second portions as the cycle period of the square signal, or perform an offset trimming on the cycle periods of the first and second portions and then take either of the offset trimmed cycle periods as the cycle period of the square signal.

3. The circuit according to claim 1, wherein the first operational amplifier circuit comprises:
an operational amplifier;
a first feedback resistor;
a second feedback resistor;
a first input resistor; and
a second input resistor,
wherein the zero crossing comparator circuit comprises an A/D converter or a comparator, a first sampling resistor, and a second sampling resistor,
wherein the first feedback resistor is connected between a negative input of the operational amplifier and a positive output of the operational amplifier,
wherein the first input resistor is connected to the negative input of the operational amplifier,
wherein the second feedback resistor is connected between a positive input of the operational amplifier and a negative output of the operational amplifier,
wherein the second input resistor is connected to the positive input of the operational amplifier,
wherein the positive output of the operational amplifier is connected with a positive input of the A/D converter or the comparator as well as a positive output of the resonance circuit,
wherein the negative output of the operational amplifier is connected with a negative input of the A/D converter or the comparator as well as a negative output of the resonance circuit,
wherein the first sampling resistor is connected between the positive input of the A/D converter or the comparator and the positive output of the resonance circuit,
wherein the second sampling resistor is connected between the negative input of the A/D converter or the comparator and the negative output of the resonance circuit, and
wherein an output of the A/D converter or the comparator is connected with the digital signal processor.

4. The circuit according to claim 1, wherein the first operational amplifier circuit comprises:
an operational amplifier;
a first feedback resistor;
a second feedback resistor;
a first input resistor;
a second input resistor; and
wherein the zero crossing comparator circuit includes an A/D converter or a comparator,
wherein the first feedback resistor is connected between a negative input of the operational amplifier and a positive output of the operational amplifier,
wherein the first input resistor is connected to the negative input of the operational amplifier,
wherein the second feedback resistor is connected between a positive input of the operational amplifier and a negative output of the operational amplifier,
wherein the second input resistor is connected to the positive input of the operational amplifier,
wherein the positive output of the operational amplifier is connected with a negative input of the A/D converter or the comparator as well as a positive output of the resonance circuit,
wherein the negative output of the operational amplifier is connected with a negative output of the resonance circuit,
wherein the positive input of the A/D converter or the comparator is connected with a reference voltage, and
wherein the output of the A/D converter or the comparator is connected with the digital signal processor.

5. A method for detecting resonance frequency, comprising:
receiving an input signal at an operational amplifier circuit and providing an output signal for a resonance circuit to store energy;
sampling a discharge current of the resonance circuit after the input signal is disabled, transforming the sampled discharge current into a sampled voltage, and outputting a square signal based on the sampled voltage; and
obtaining a resonance frequency based on the square signal.

6. The method according to claim 5, wherein the obtaining the resonance frequency based on the square signal comprises:
determining a portion of the square signal corresponding to a first cycle; and
calculating, based on a clock frequency, a cycle period of the portion as the cycle period of the square signal; or,
determining a first portion of the square signal corresponding to the first cycle and a second portion of the square signal corresponding to a second cycle following the first cycle,
calculating the cycle period of each of the first and second portions based on the clock frequency, and
taking an average of the cycle periods of the first and second portions as the cycle period of the square signal, or performing an offset trimming on the cycle periods of the first and second portions and then taking either of the offset trimmed cycle periods of the first and second portions as the cycle period of the square signal.

7. The method according to claim 5, wherein the sampling the discharge current of the resonance circuit, transforming the sampled discharge current into the sampled voltage, and outputting the square signal based on the sampled voltage comprise:
sampling the discharge currents at both outputs of the resonance circuit, transforming the sampled discharge currents into sampled voltages, and comparing the two sampled voltages to output the square signal.

8. The method according to claim 5, wherein the sampling the discharge current of the resonance circuit, transforming the sampled discharge current into the sampled voltage, and outputting the square signal based on the sampled voltage comprise:
sampling the discharge current at one output of the resonance circuit, transforming the sampled discharge current into a sampled voltage, and comparing the sampled voltage with a predetermined reference voltage to output the square signal.

9. An integrated circuit, comprising:
a resonance frequency detection circuit comprises:
a first operational amplifier circuit;
a resonance circuit;
a zero crossing comparator circuit; and
a digital signal processor,
wherein the first operational amplifier circuit is configured to receive an input signal and to provide an output signal for the resonance circuit to store energy,
wherein the resonance circuit is configured to store energy based on the output signal of the first operational amplifier circuit, and to discharge after the input signal is disabled,
wherein the zero crossing comparator circuit is configured to sample a discharge current of the resonance circuit after the input signal is disabled, to transform the sampled discharge current to a sampled voltage, and to output a square signal to the digital signal processor based on variation of the sampled voltage, and
wherein the digital signal processor is configured to obtain a resonance frequency based on the square signal.

10. The integrated circuit according to claim 9, wherein the digital signal processor is configured to:
determine a portion of the square signal corresponding to a first cycle; and
calculate, based on a clock frequency, a cycle period of the portion as the cycle period of the square signal; or wherein the digital signal processor is configured to:
determine a first portion of the square signal corresponding to the first cycle and a second portion of the square signal corresponding to a second cycle following the first cycle;
calculate the cycle period of each of the first and second portions based on the clock frequency; and
take an average of the cycle periods of the first and second portions as the cycle period of the square signal, or perform an offset trimming on the cycle periods of the first and second portions, and then take either of the offset trimmed cycle periods of the first and second portions as the cycle period of the square signal.

11. The integrated circuit according to claim 9, wherein the first operational amplifier circuit comprises:
an operational amplifier;
a first feedback resistor;
a second feedback resistor;
a first input resistor; and
a second input resistor,
wherein the zero crossing comparator circuit comprises an A/D converter or a comparator, a first sampling resistor, and a second sampling resistor,
wherein the first feedback resistor is connected between a negative input of the operational amplifier and a positive output of the operational amplifier,
wherein the first input resistor is connected to the negative input of the operational amplifier,
wherein the second feedback resistor is connected between a positive input of the operational amplifier and a negative output of the operational amplifier,
wherein the second input resistor is connected to the positive input of the operational amplifier,
wherein the positive output of the operational amplifier is connected with a positive input of the A/D converter or the comparator as well as a positive output of the resonance circuit,
wherein the negative output of the operational amplifier is connected with a negative input of the A/D converter or the comparator as well as a negative output of the resonance circuit,
wherein the first sampling resistor is connected between the positive input of the A/D converter or the comparator and the positive output of the resonance circuit,
wherein the second sampling resistor is connected between the negative input of the A/D converter or the comparator and the negative output of the resonance circuit, and
wherein an output of the A/D converter or the comparator is connected with the digital signal processor.

12. The integrated circuit according to claim 9, wherein the first operational amplifier circuit comprises:
an operational amplifier;
a first feedback resistor;
a second feedback resistor;
a first input resistor;
a second input resistor; and
wherein the zero crossing comparator circuit includes an A/D converter or a comparator,
wherein the first feedback resistor is connected between a negative input of the operational amplifier and a positive output of the operational amplifier,
wherein the first input resistor is connected to the negative input of the operational amplifier,
wherein the second feedback resistor is connected between a positive input of the operational amplifier and a negative output of the operational amplifier,
wherein the second input resistor is connected to the positive input of the operational amplifier,
wherein the positive output of the operational amplifier is connected with a negative input of the A/D converter or the comparator as well as a positive output of the resonance circuit,
wherein the negative output of the operational amplifier is connected with a negative output of the resonance circuit,
wherein the positive input of the A/D converter or the comparator is connected with a reference voltage, and
wherein the output of the A/D converter or the comparator is connected with the digital signal processor.
